(19) United States
(12) Patent Application Publication
(10) Pub. No.: US 2025/0022727 A1
(43) Pub. Date: Jan. 16, 2025

(54) DIE BONDER HAVING A ROTARY BOND ARM ACTUATOR

(71) Applicant: ASMPT Singapore Pte. Ltd., Singapore (SG)

(72) Inventors: Ka Shing KWAN, Singapore (SG); Dafu XU, Singapore (SG); Ping Kong CHOY, Singapore (SG); Jia Hua JONG, Singapore (SG)

(21) Appl. No.: 18/221,449

(22) Filed: Jul. 13, 2023

(51) Int. Cl. H01L 21/67

(52) U.S. Cl. CPC H01L 21/67144; H01L 21/67253; H01L 21/67259

(57) ABSTRACT

A semiconductor die bonding device has a bond arm body, a collet attached at a first end of the bond arm body for holding a semiconductor die during a pick-and-place operation, and a voice coil actuator located at a second end of the bond arm body for driving the bond arm body to rotate about a pivot positioned between the collet and the voice coil actuator. The voice coil actuator includes a pair of arc magnets having concave arced surfaces facing the pivot that form an arc-shaped gap between the arc magnets, and an arc coil including a concave arced surface disposed within the arc-shaped gap that is configured to be movable relative to the arc magnets.

### FIELD OF THE INVENTION

The invention relates to a die bonding operation where a semiconductor die or chip is picked up by a bonding device mounted on a bond head incorporated in a die bonding apparatus, and in particular to a bonding device having a rotary actuator for driving pick-and-place operations of the bonding apparatus.

### BACKGROUND AND PRIOR ART

A bond head of a die bonding apparatus is used to pick up a semiconductor die or chip from a supply of semiconductor dies, such as a wafer which is mounted on a movable wafer table. After picking up a semiconductor die with its bond arm, the bond arm then places and bonds the semiconductor die onto a bond pad on a substrate or carrier, which may be in the form of a lead frame or other substrate. Such a process is known as die bonding.

Conventionally, the bond head is driven by a positioning table on which it is mounted. The positioning table may be a movable X-Y table, or a rotary table, and it cooperates with a workstation including the supply of semiconductor dies or substrate which is separately mounted onto another movable X-Y table or rotary table. A bond arm is usually mounted on the bond head, and it is driven linearly along the Z axis by a linear motor to move upwards or downwards, which typically in practice would be in directions towards or away from a semiconductor die. Such a Z axis linear motor may be a motor coupled between the bond head and the positioning table for moving the entire bond head, or between the bond arm and the bond head to move the bond arm relative to the bond head.

An example of a prior art rotary table is described in patent publication number CN115360127A entitled, “Double-end Driving Device for Die Bond Process”. After a rotary drive motor rotates a bond head assembly to position a pair of bond arms to positions above a target semiconductor die and/or placement location respectively, a linear vertical drive mechanism is operative to drive the entire bond head assembly comprising the bond arms to displace linearly in upward and downward directions.

A disadvantage of conventional bond heads that are carried by positioning tables and driven by linear actuators to move along the Z axis is that the bond arm is limited in its driving force and acceleration in a high-speed automatic die bonder. This is due to a relatively heavy bond head that is being carried by the positioning table when the bond head is being moved along its respective motion axes. Alternatively, where the bond arm driven by a linear motor to move relative to a bond head on which it is mounted, the linear motor complicates the design of the bond head and adds significantly to a weight of the bond head when it is being moved by the positioning table.

It would thus be beneficial to allow motion of the bond arm along the Z axis to be driven independently of the bond head with a reduced inertia in order to increase an acceleration and speed of the bond arm. This would help to increase throughput of the pick-and-place operations performed by the bond head.

### SUMMARY OF THE INVENTION

It is thus an object of the invention to seek to provide a die bonder having a bonding device which is capable of faster acceleration and speed as compared to the prior art.

Accordingly, the invention provides a semiconductor die bonding device, comprising: a bond arm body; a collet attached at a first end of the bond arm body for holding a semiconductor die during a pick-and-place operation; a voice coil actuator located at a second end of the bond arm body for driving the bond arm body to rotate about a pivot positioned between the collet and the voice coil actuator; wherein the voice coil actuator further comprises a pair of arc magnets having concave arced surfaces facing the pivot that form an arc-shaped gap between the arc magnets, and an arc coil including a concave arced surface disposed within the arc-shaped gap that is configured to be movable relative to the arc magnets.

It would be convenient hereinafter to describe the invention in greater detail by reference to the accompanying drawings which illustrate specific preferred embodiments of the invention. The particularity of the drawings and the related description is not to be understood as superseding the generality of the broad identification of the invention as defined by the claims.

### BRIEF DESCRIPTION OF THE DRAWINGS

An exemplary die bonding device incorporating the invention will now be described with reference to the accompanying drawings, in which:

FIG. 1 is an isometric view of a bond arm according to the preferred embodiment of the invention;

FIG. 2 is a side view of the bond arm illustrated in FIG. 1;

FIG. 3 is a side view of the bond arm that is mounted on a single arm bond head which is movable by a positioning table in the X, Y and Z directions; and

FIG. 4 is a side view of a pair of bond arms according to the preferred embodiment of the invention that is mounted on opposite sides of a rotary dual arm bond head.

### DETAILED DESCRIPTION OF THE PREFERRED EMBODIMENT OF THE INVENTION

FIG. 1 is an isometric view of a semiconductor die bonding device or bond arm 10 according to the preferred embodiment of the invention. The bond arm 10 generally includes an elongated bond arm body 12, and a collet 14 that is affixed or attached at a first end of the bond arm body 12 for holding a semiconductor die (not shown) during a pick-and-place process. For actuating an up-and-down motion of the collet 14, a motor in the form of an arc voice coil actuator 16 is situated at a second end of the bond arm body 12 opposite to where the collet 14 is attached.

The bond arm body 12 is pivoted at a pivot point 22 for moving in an arc motion about the pivot point 22, and the arc motion of the bond arm body 12 about the pivot point 22 is in turn actuated by the arc voice coil actuator 16. In the illustrated embodiment, the arc voice coil actuator 16 includes a coil that is movable relative to permanent magnets by way of electromagnetic interaction between the coil and the permanent magnets when current flows through the coil, which allows the arc voice coil actuator 16 to accomplish an actuator arc motion path 28.

This arc voice coil actuator 16 is thus unique in that it utilizes a pair of arc-shaped arc magnets 18 that is fixedly arranged along an arc, and a movable arc-shaped arc coil 20 positioned between the pair of arc magnets 18. The arc magnets 18 have concave arced surfaces facing the pivot point 22. An arc-shared gap 19 is formed between the arc magnets 18, within which the arc coil 20 also having a concave arced surface facing the pivot point 22 is disposed. Thus, the arc coil 20 is configured to be movable relative to the arc magnets 18 within the arc-shaped gap 19.

The arc coil 20 is fixedly connected to the bond arm body 12 by a first connecting link 40 coupling a top edge of the arc coil 20 to the bond arm body 12, and a second connecting link 42 coupling a bottom edge of the arc coil 20 to the bond arm body 12. An angular range of motion of the arc coil 20 relative to the arc magnets 18 is designed to be less than an angular distance between the first and second connecting links 40, 42. When actuated by the arc voice coil actuator 16, the bond arm body 12 and the collet 14 are driven to turn along a bond arm arc motion path 26 that is directionally opposite to the actuator arc motion path 28. The collet 14 is configured to hold a semiconductor die during a pick-and-place process.

When the arc coil 20 is actuated to move relative to the arc magnets 18 by a current flowing through the arc coil 20, such actuation causes rotation of the bond arm body 12 about the pivot point 22, and the collet 14 is in turn driven to move in an opposite direction to movement of the arc coil 20. Accordingly, the collet 14 may be moved downwards to pick up a semiconductor die (not shown) at a tip of the collet 14, then moved upwards to convey the semiconductor die to a placement position, and finally moved downwards to bond the semiconductor die at the placement position.

A position encoder 24 is coupled to the bond arm body 12 to determine a position and angular orientation of the bond arm body 12 during its rotary motion about the pivot point 22.

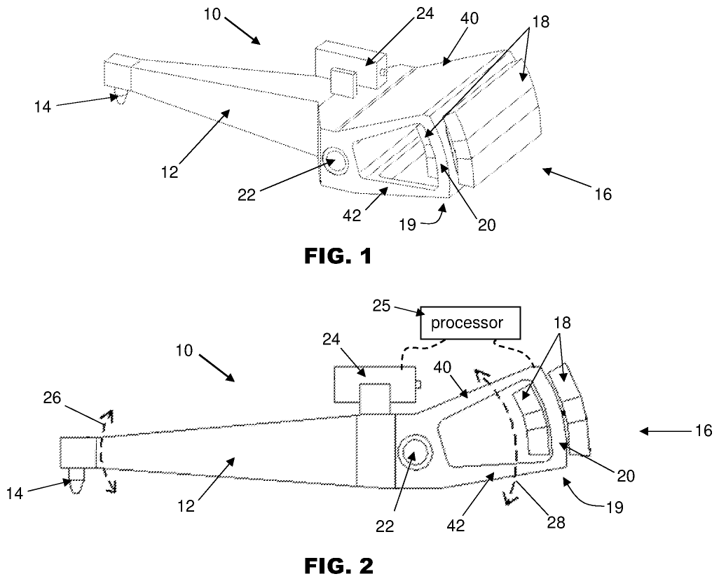

FIG. 2 is a side view of the bond arm 10 illustrated in FIG. 1. It illustrates that the first end of the bond arm body 12 including the collet 14 is drivable to move along a bond arm arc motion path 26, and the arc coil 20 is drivable to move along an actuator arc motion path 28. The bond arm arc motion path 26 and the actuator arc motion path 28 are generally directionally opposite at all times during rotary motion of the bond arm body 12 about the pivot point 22.

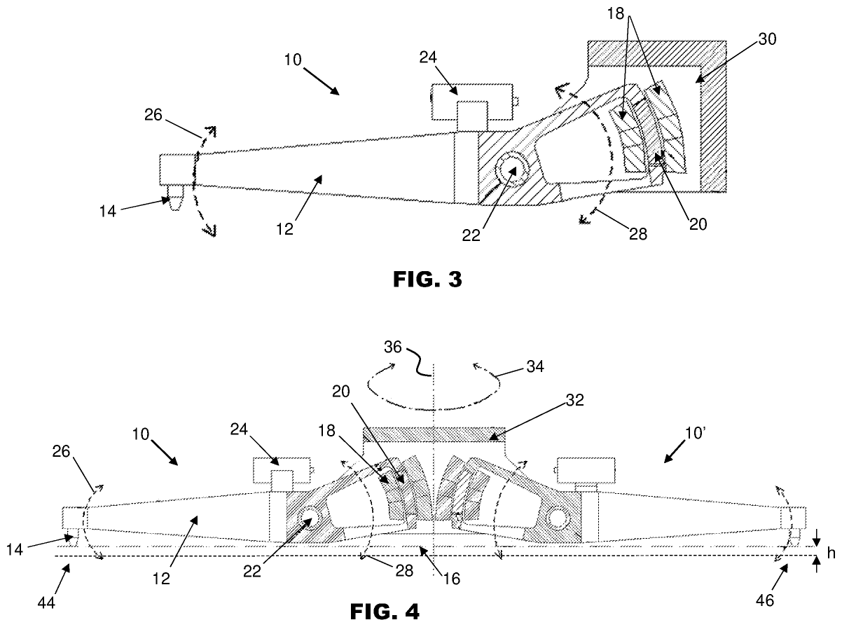

FIG. 3 is a side view of the bond arm 10 that is mounted on a single arm bond head 30 which is movable by a positioning table (not shown) in orthogonal X, Y and Z directions in a three-dimensional space according to a Cartesian coordinate system. The bond arm 10 is carried by the single arm bond head 30, which generally positions the collet 14 of the bond arm body 12 between multiple pick-up and placement positions. Positioning of the single arm bond head 30 may be driven by a conventional XYZ table. For instance, the single arm bond head 30 may move the collet 14 to a position over a semiconductor die to be picked up, leaving a gap between the collet 14 and the semiconductor die.

Thereafter, the arc voice coil actuator 16 is operative to provide a current in the arc coil 20 for driving the arc coil 20 to move in an anti-clockwise direction along the actuator arc motion path 28. The collet 14 is thus made to also move anti-clockwise along the bond arm arc motion path 26 to be driven downwards to softly touch the semiconductor die. Once the collet 14 contacts the semiconductor die, a vacuum suction force is generated at a mouth of the collet 14 in order to hold the semiconductor die.

The arc voice coil actuator 16 is then operative to provide a current in the arc coil 20 in an opposite direction to drive the arc coil 20 to move in a clockwise direction along the actuator arc motion path 28. The collet 14 is made to also move clockwise along the bond arm arc motion path 26 while holding the semiconductor die, hence picking up the semiconductor die. Thereafter, the single arm bond head 30 conveys the bond arm body 12 in the X, Y and Z directions while the single arm bond head 30 is driven by the conventional XY table to a placement position.

At the placement position where the semiconductor die is to be bonded, the bond arm body 12 positions the collet 14 such that a gap is left between the semiconductor die and the bonding position. Here, the arc voice coil actuator 16 similarly provides a current in the arc coil 20 to driving the arc coil 20 to move in an anti-clockwise direction to move the collet 14 anti-clockwise to place the semiconductor die onto the placement position, whereat the semiconductor is placed onto a die carrier or substrate. After the semiconductor die has been placed correctly, the vacuum suction force at a mouth of the collet 14 is switched off and the collet 14 releases and separates from the semiconductor die as the arc voice coil actuator 16 drives the collet 14 to move upwards.

The die bonding apparatus will repeat the above die bonding sequence for other semiconductor dies from the supply of semiconductor dies. The position encoder 24 is used to provide accurate position feedback to a processor 25 during the die bonding process. By comparing position feedback from the position encoder 24 and the current flow intensity in the arc coil 20, the processor 25 may detect and control an impact force exerted by the collet 14 onto the semiconductor die during the pick-and-place process in order to minimize the bonding force and avoid damage to the semiconductor die throughout the die bonding sequence.

FIG. 4 is a side view of first and second bond arms 10, 10′ according to the preferred embodiment of the invention that are mounted on opposite sides of a rotary dual arm bond head 32. The rotary dual arm bond head 32 is coupled to a rotary drive (not shown) which rotates the respective bond arms 10, 10′ between a pick-up position 44 where a supply of semiconductor dies is located, and a placement position 46 including various bond pads where the semiconductor dies should be bonded. The respective bond arm bodies 12 of the two bond arms 10, 10′ are separated by an angle of 180 degrees. As the second bond arm 10′ may have the same construction as the first bond arm 10 which has already been described above in detail, the constitution of each bond arm 10, 10′ will not be described in any further detail in this embodiment.

The rotary dual arm bond head 32 is drivable by the rotary drive to rotate along a theta motion path 34 about a central rotary axis 36 is that centrally located between the dual bond arms 10, 10′. Thus, the pick-up and placement positions 44, 46 would be located on opposite sides of the central rotary axis 36. Unlike for the single arm bond head 30, the rotary dual arm bond head 32 need not carry the dual bond arms 10, 10′ to move vertically (or in the Z axis) at all. This is because the pick-up position 44 and the placement position 46 may already be set at one or more heights, h, that is/are within a range of motion of the collet 14 along the bond arm arc motion path 26.

Hence, when the first bond arm 10 is rotated to be positioned above the pick-up position 44, there is a gap between a tip of the collet 14 and a pick-up or placement position 44, 46 which is equal to the height h. The arc voice coil actuator 16 may drive the collet 14 to move downwards to close the gap so as to contact a semiconductor die to be picked up. After the semiconductor die has been picked up by the collet 14, the arc coil 20 may be moved in the opposite direction to lift the semiconductor die from the pick-up position 44.

The first bond arm 10′ is then conveyed to a position above the placement position 46 by rotation of the rotary dual arm bond head 32 by a 180-degree angle. At this position, there will again be a gap between the semiconductor die and the placement position 46. At the same time, rotation of the rotary dual arm bond head 32 also causes the second bond arm 10′ to be located above the pick-up position 44. Therefore, while the collet 14 of the first bond arm 10 is moved downwards by the arc voice coil actuator 16 to bond the semiconductor die at the placement position 46, the second bond arm 10′ is capable of simultaneously picking up another semiconductor die for bonding at the placement position.

Once the semiconductor die has been bonded by the first bond arm 10 and another semiconductor die has been picked up by the second bond arm 10′, the rotary dual arm bond head 32 is again rotated by a 180-degree angle, which locates the first bond arm 10 over the pick-up position 44 and the second bond arm 10′ over the placement position 46. At this time, the first bond arm 10 can pick up a further semiconductor die while the second bond arm 10′ simultaneously bonds the semiconductor die that it had picked up.

The above process may be repeated until all the semiconductor dies have been picked up from the pick-up position 44 and bonded at the placement position 46. With the rotary dual arm bond head 32 configuration, each bond arm body 10, 10′ is able to perform the above die bonding process in sequence or in parallel without any performance losses. Thus, the throughput of the dual arm embodiment illustrated in FIG. 4 can be much higher than that for the single arm embodiment illustrated in FIG. 3.

The rotary dual arm bond head 32 is able to achieve high-speed rotary motion along the theta motion path 34 about the rotary axis 36. The arc voice coil actuator 14 helps to provide a compact structure with a lower inertia. By comparing position feedback from the position encoder 24 and the current flow intensity in the arc coil 20, the processor 25 may detect and control the impact force exerted by the collet 14 during die pick-and-place processes for minimizing the bonding force to avoid damage to the semiconductor die. A travel path of the rotary dual arm bond head 32 about the rotary axis 36 center line is further configurable to match different die bond platforms to each bond arm body 10, 10′ for conducting the above die bonding process in sequence or in parallel.

It should be appreciated that the bond arm and bond head according to the preferred embodiment of the invention incorporates a low-inertia high-speed arc voice coil driven die bonding arm for use with an automatic die bonder. An arc motion instead of a traditional linear motion is provided in the Z axis for semiconductor die pick-and-place processes. The arc motion adopts a rotary pivot and lever structure. Conventional vertical linear pick-and-place motions are replaced by an arc-shaped arc voice coil actuator 16 instead. Using the apparatus according to the preferred embodiment of the invention, a larger actuator torque output is achievable for improving motion speed, to sustain higher accelerations and to practically reduce bonding impact force without affecting the effectiveness of die bonding operations.

The die bond head is configurable with one bond arm or two bond arms based on different application needs without losing its performance, as shown in FIG. 3 and FIG. 4.

Driving the bond arm body 12 up and down with an arc motion instead of the conventional linear motion helps to generate a larger torque within a limited space. The rotational pivot point 22 may be lowered appropriately to reduce a height difference h between a bonding point (i.e., a bottom surface of collet 14) and the pick-up and/or placement locations 44, 46 so as to maintain a high level of parallelism between a lower surface of the semiconductor die and the surface where the semiconductor die is picked up or bonded.

The bonding force may be controlled over a wide range. Such a compact structure achieves a low inertia for vertical motion of the bond arm body 12 for either a single bond arm configuration, or even more beneficially, to a dual bond arm configuration.

The invention described herein is susceptible to variations, modifications and/or additions other than those specifically described and it is to be understood that the invention includes all such variations, modifications and/or additions which fall within the spirit and scope of the above description.

1. A semiconductor die bonding device, comprising:
a bond arm body;
a collet attached at a first end of the bond arm body for holding a semiconductor die during a pick-and-place operation;
a voice coil actuator located at a second end of the bond arm body for driving the bond arm body to rotate about a pivot positioned between the collet and the voice coil actuator;
wherein the voice coil actuator further comprises a pair of arc magnets having concave arced surfaces facing the pivot that form an arc-shaped gap between the arc magnets, and an arc coil including a concave arced surface disposed within the arc-shaped gap that is configured to be movable relative to the arc magnets.

2. The semiconductor die bonding device as claimed in claim 1, further comprising first and second connecting links coupling top and bottom edges of the arc coil respectively to the bond arm body, wherein an angular range of motion of the arc coil relative to the arc magnets is less than an angular distance between the first and second connecting links.

3. The semiconductor die bonding device as claimed in claim 1, further comprising a position encoder coupled to the bond arm body for determining an angular orientation of the bond arm body during its rotary motion about the pivot.

4. The semiconductor die bonding device as claimed in claim 3, further comprising a processor operative to compare a position feedback from the position encoder with a current flow intensity in the arc coil, for controlling an impact force exerted by the collet.

5. The semiconductor die bonding device as claimed in claim 1, wherein the bond arm body is mounted on a single bond arm bond head, the single bond arm bond head being movable along three orthogonal axes for positioning the collet at multiple pick-up and placement positions.

6. The semiconductor die bonding device as claimed in claim 1, wherein the bond arm body is mounted on a rotary dual arm bond head, which includes a pair of bond arm bodies separated by an angle of 180 degrees.

7. The semiconductor die bonding device as claimed in claim 6, wherein the rotary dual arm bond head is operative to rotate the respective bond arms along a theta motion path about a central rotary axis, a pick-up position and a placement position whereat the pair of bond arm bodies are positionable being located on opposite sides of the central rotary axis.

8. The semiconductor die bonding device as claimed in claim 7, wherein the arc coil is drivable to move along an actuator arc motion path and the collet is drivable to move along a bond arm arc motion path that is directionally opposite to the actuator arc motion path.

9. The semiconductor die bonding device as claimed in claim 8, wherein the pick-up position and placement position are set at one or more heights that are within a range of motion of the collet along the bond arm arc motion path.

10. The semiconductor die bonding device as claimed in claim 9, wherein the one or more heights are set such that there is a gap between the collet and the pick-up position or placement position when the collet is rotated to the respective position, and the voice coil actuator is operative to drive the collet to close the said gap.
